(19) United States
(12) Patent Application Publication
(10) Pub. No.: US 2015/0237718 A1
(43) Pub. Date: Aug. 20, 2015

(54) POWER SEMICONDUCTOR DEVICE

(71) Applicant: Mitsubishi Electric Corporation, Tokyo (JP)

(72) Inventors: Yoshihiro YAMAGUCHI, Tokyo (JP); Tatsunori YANAGIMOTO, Tokyo (JP); Hidetoshi ISHIBASHI, Tokyo (JP)

(73) Assignee: Mitsubishi Electric Corporation, Tokyo (JP)

(21) Appl. No.: 14/535,639

(22) Filed: Nov. 7, 2014

(30) Foreign Application Priority Data
Feb. 17, 2014 (JP) 2014-027200

(51) Int. Cl. H05K 1/02; H05K 1/11; H05K 1/03; H05K 1/09; H01L 23/14; H05K 1/18

(52) U.S. Cl. CPC H05K 1/0271; H01L 23/142; H05K 1/181; H05K 1/0306; H05K 1/092; H05K 1/111

(57) ABSTRACT

A circuit board having a power semiconductor element mounted thereon includes an insulating plate, a bonding pattern, a circuit pattern, and a pad plate. The insulating plate is made of aluminum nitride ceramic and has a first surface and a second surface opposite to the first surface. The bonding pattern is bonded to the first surface of the insulating plate and made of any of aluminum and aluminum alloy. The circuit pattern is bonded to the second surface of the insulating plate and made of any of aluminum and aluminum alloy. The pad plate is bonded to the circuit pattern, only partially covers the circuit pattern, and is made of any of copper and copper alloy.

### BACKGROUND OF THE INVENTION

1. Field of the Invention

The present invention relates to a power semiconductor device and more particularly to a power semiconductor device including a circuit board having a power semiconductor element mounted thereon.

2. Description of the Background Art

A power semiconductor element, such as an insulated gate bipolar transistor (IGBT) and a diode, provided in a power module generates a great amount of heat in use. Thus, a circuit board having the power semiconductor element mounted thereon is needed to withstand stress caused by temperature variations under a heat cycle. To efficiently remove the heat from the power semiconductor element, a ceramic serving as a base material for the circuit board is required to have high thermal conductivity. Ceramic materials are typified by an aluminum nitride and a silicon nitride.

The aluminum nitride ceramic has high thermal conductivity but does not necessarily have high mechanical strength as a material. Thus, a structure for reducing the above-mentioned stress may be required.

The silicon nitride ceramic has high mechanical strength, thereby being suitable for withstanding the stress. The thermal conductivity of the silicon nitride ceramic is inferior to that of the aluminum nitride ceramic, but the thermal conductivity of the silicon nitride ceramic has been increasingly improved in recent times.

Two conventional technologies related to a circuit board are as follows.

As disclosed in Japanese Patent Application Laid-Open No. 2003-78086 (Patent Document 1), a layer made of aluminum or aluminum alloy and a layer made of copper or copper alloy are laminated in the stated order on a front surface of a ceramic plate serving as an insulating layer. The layer of aluminum or aluminum alloy which is a material softer than copper or copper alloy reduces thermal stress applied on the ceramic plate.

As disclosed in Japanese Patent Application Laid-Open No. 2008-147307 (Patent Document 2), a circuit plate made of copper or copper alloy is provided on a silicon nitride ceramic board.

The conventional technologies mount components on a circuit board in manufacturing a power semiconductor device and bond the components to copper or copper alloy. However, the bonding to copper or copper alloy is sometimes not suitable, depending on a kind of the component, and this may result in insufficient electrical bonding reliability. Incompatibility as mentioned above may lead to a problem, particularly in a case of a direct bonding such as an ultrasonic bonding more suitable for use under high temperature than a solder bonding. For example, when an aluminum wire is bonded to a copper pattern by the ultrasonic bonding, an oxide film at a bonding interface between the aluminum and the copper causes the insufficient electrical bonding reliability. This problem requires more consideration in a case where a power semiconductor element is used in high temperature. In recent times, a silicon carbide (SiC) or a gallium nitride (GaN) which is more suitable for operation in high temperature than a silicon (Si) is increasingly applied as a material for the power semiconductor element. In order not to lose the advantage, the electrical bonding reliability as described above particularly requires improvements.

### SUMMARY OF THE INVENTION

The present invention has been made in view of the above-mentioned problems, and an object thereof is to provide a power semiconductor device capable of increasing electrical bonding reliability.

According to a first aspect of the present invention, a power semiconductor device includes a power semiconductor element and a circuit board having the power semiconductor element mounted thereon. The circuit board includes an insulating plate, a bonding pattern, a circuit pattern, and a pad plate. The insulating plate is made of aluminum nitride ceramic and has a first surface and a second surface opposite to the first surface. The bonding pattern is bonded to the first surface of the insulating plate and made of any of aluminum and aluminum alloy. The circuit pattern is bonded to the second surface of the insulating plate and made of any of aluminum and aluminum alloy. The pad plate is bonded to the circuit pattern, only partially covers the circuit pattern, and is made of any of copper and copper alloy.

According to another aspect of the present invention, a power semiconductor device includes a power semiconductor element and a circuit board having the power semiconductor element mounted thereon. The circuit board includes an insulating plate, a bonding pattern, a circuit pattern, and a pad plate. The insulating plate is made of silicon nitride ceramic and has a first surface and a second surface opposite to the first surface. The bonding pattern is bonded to the first surface of the insulating plate and made of any of copper and copper alloy. The circuit pattern is bonded to the second surface of the insulating plate and made of any of copper and copper alloy. The pad plate is bonded to the circuit pattern, only partially covers the circuit pattern, and is made of any of aluminum and aluminum alloy.

The power semiconductor device of the present invention can increase the electrical bonding reliability.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a diagram schematically showing a configuration of a power module as a power semiconductor device in a first preferred embodiment of the present invention and is a cross-sectional view taken along a I-I line of FIG. 2;

FIG. 2 is a schematic cross-sectional view taken along a II-II line of FIG. 1;

FIG. 3 is a diagram showing a configuration of a power module of a comparative example and is a cross-sectional view taken along a III-III line of FIG. 4;

FIG. 4 is a cross-sectional view taken along a IV-IV line of FIG. 3;

FIG. 5 is a diagram schematically showing a configuration of a power module as a power semiconductor device in a second preferred embodiment of the present invention and is a cross-sectional view taken along a V-V line of FIG. 6; and

FIG. 6 is a schematic cross-sectional view taken along a VI-VI line of FIG. 5.

### DESCRIPTION OF THE PREFERRED EMBODIMENTS

Preferred embodiments of the present invention will be described below with reference to the drawings. The same or corresponding portions in the drawings have the same reference numerals, and the descriptions will not be repeated.

### First Preferred Embodiment

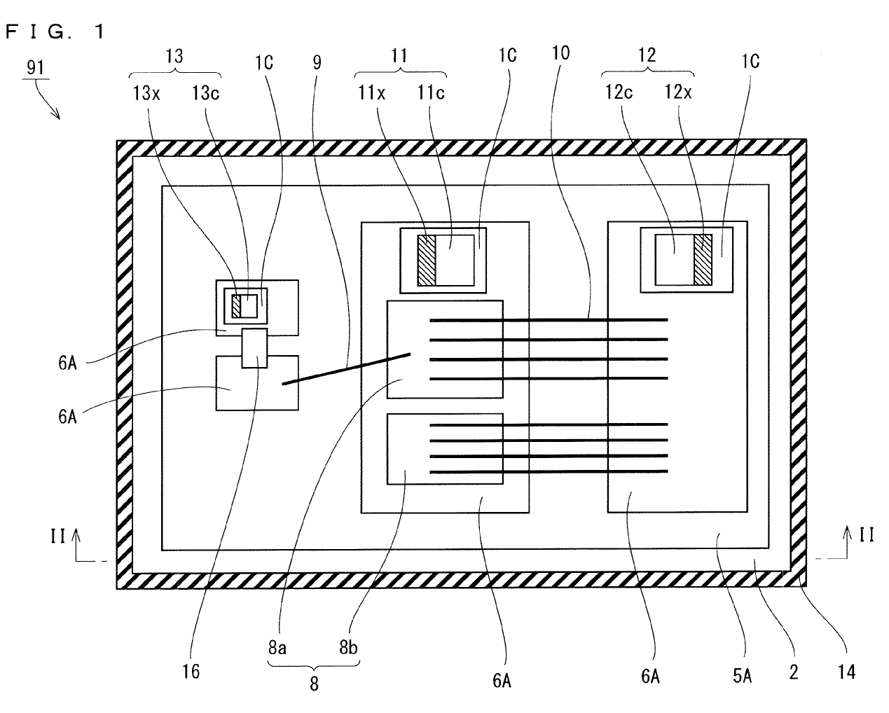

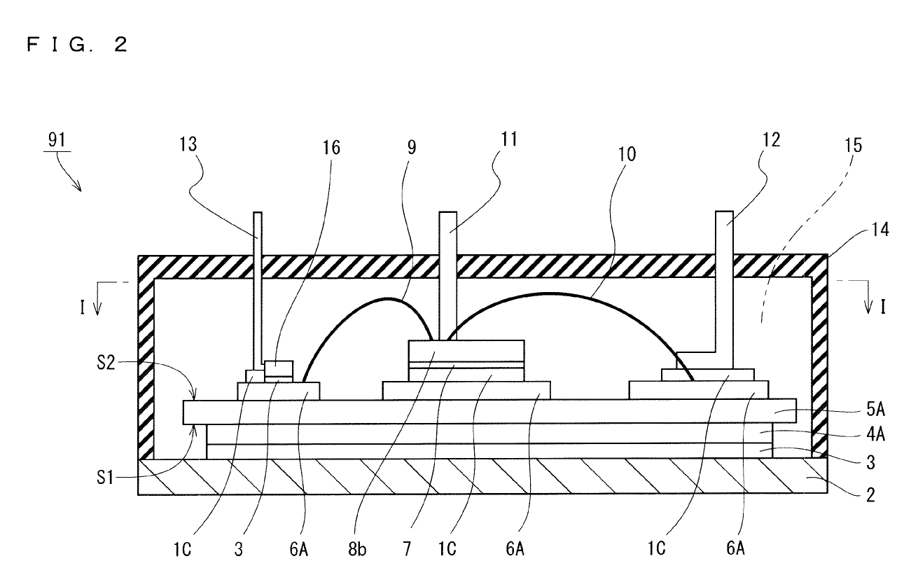

With reference to FIGS. 1 and 2, a power module 91 (power semiconductor device) includes a circuit board and power semiconductor elements 8 mounted on the circuit board.

Specifically, the power semiconductor element 8 includes a switching semiconductor element 8a such as an insulated gate bipolar transistor (IGBT) and a rectifying semiconductor element 8b such as a power diode. The circuit board includes an insulating plate 5A, a bonding pattern 4A, circuit patterns 6A, and pad plates 1C.

The insulating plate 5A is made of aluminum nitride ceramic. The insulating plate 5A has a lower surface S1 (first surface) and an upper surface S2 (second surface opposite to first surface).

The bonding pattern 4A is bonded to the lower surface Si of the insulating plate 5A. The bonding pattern 4A is made of aluminum or aluminum alloy. The circuit patterns 6A are bonded to the upper surface S2 of the insulating plate 5A. The circuit patterns 6A are made of aluminum or aluminum alloy. The bonding pattern 4A and the circuit patterns 6A can be bonded to the insulating plate 5A by a direct bonded aluminum (DBA) or an active metal brazing (AMB).

The pad plates 1C are made of copper or copper alloy. The pad plates 1C are bonded to the circuit patterns 6A. This bonding can be performed by a solid phase diffusion bonding in which the insulating plate 5A and the pad plates 1C are pressurized in high temperature in a vacuum. The pad plates 1C only partially cover the circuit patterns 6A. Unlike electrodes which will be described later, the pad plates 1C are housed in a case 14 without protruding to the outside of the case 14. The pad plates 1C preferably have a flat plate shape.

The power semiconductor elements 8 are bonded to the pad plate 1C, and in this preferred embodiment, the plurality of power semiconductor elements 8 are bonded to one pad plate 1C. Each of the power semiconductor elements 8 is preferably bonded with a bonding material 7 containing silver.

The power semiconductor elements 8 are mounted on the circuit board prepared in advance. In other words, the power semiconductor elements 8 are mounted after the completion of bonding steps of manufacturing the circuit board. Thus, conditions of the bonding steps, such as the solid phase diffusion bonding which pressurizes in high temperature as described above, can be selected with great flexibility without considering effects on the power semiconductor elements 8 and wires which may be accompanied therewith. Moreover, the components bonded to each other in this bonding usually have a plate shape which makes the bonding easy. In addition, each bonding area is relatively great. Therefore, it is relatively easy for the bonding to obtain bonding reliability even if the different kinds are bonded to each other such that aluminum or aluminum alloy is bonded to copper or copper alloy.

The power module 91 includes electrodes that are directly bonded to the pad plates 1C and made of any of copper or copper alloy. The electrodes are preferably bonded to the pad plates 1C by the ultrasonic bonding. Specifically, the power module 91 includes an anode Cu electrode 11, a cathode Cu electrode 12, and a control Cu electrode 13. These electrodes, namely, the external electrodes extend from the inside of the case 14 to the outside.

The power module 91 includes a gate Al wire 9 and main Al wires 10 which are made of aluminum and aluminum alloy. The gate Al wire 9 and the main Al wires 10 are each bonded to the power semiconductor element 8 at one end. Furthermore, the gate Al wire 9 and the main Al wires 10 are each directly bonded to the circuit patterns 6A at the other end, and they are preferably bonded by the solid phase diffusion bonding, for example, the ultrasonic bonding.

The power module 91 may include passive components such as a gate resistor 16 connected to the circuit patterns 6A. The gate resistor 16 may be bonded with a solder layer 3, for example.

The power module 91 includes a metal base plate 2, the case 14, and a filling portion 15. To make the diagram easy to see, the shape of the filling portion 15 is omitted in the diagram. The metal base plate 2 is bonded to the bonding pattern 4A to be mounted on the circuit board. This bonding may be performed with the solder layer 3, for example. The case 14 on the metal base plate 2 houses the circuit board having the power semiconductor elements 8 mounted thereon. The case 14 can be mounted with screws or a silicone gel. The filling portion 15 is made of insulator filling in the case 14 and seals the power semiconductor elements 8 on the circuit board. A material for the filling portion 15 is, for example, the silicone gel.

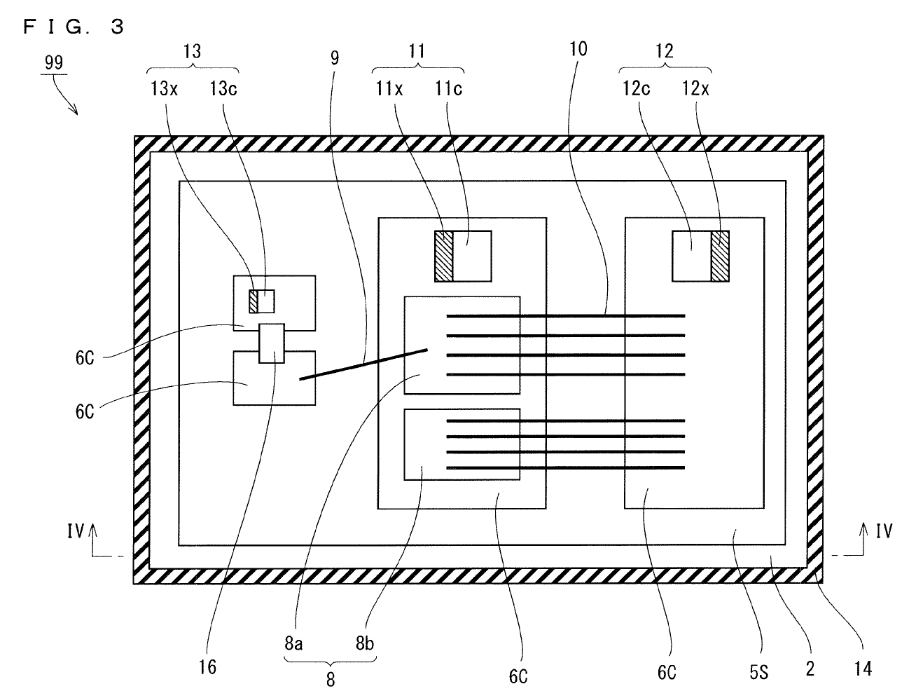

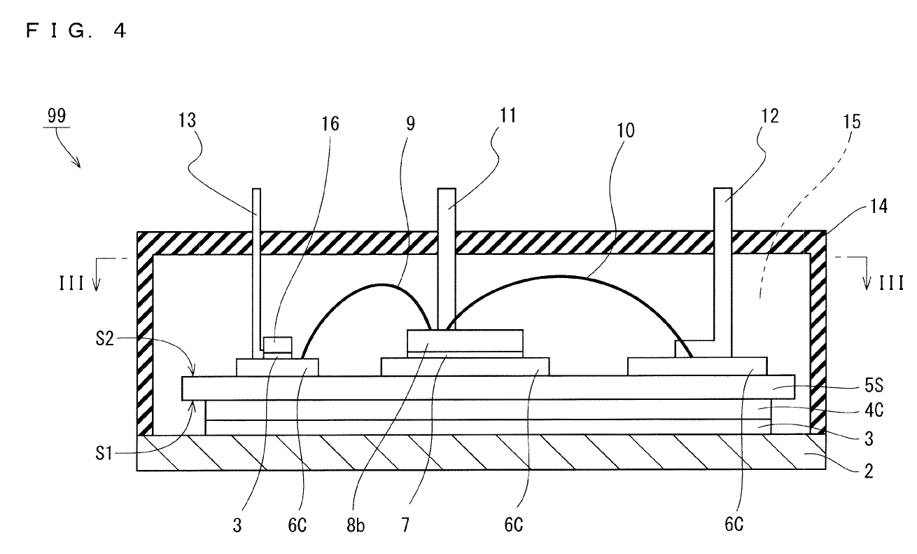

With reference to FIGS. 3 and 4, a power module 99 of a comparative example includes a bonding pattern 4C, an insulating plate 5S, and circuit patterns 6C in place of the bonding pattern 4A, the insulating plate 5A, and the circuit patterns 6A as described above, respectively. The bonding pattern 4C and the circuit patterns 6C are made of copper or copper alloy. The insulating plate 5S is made of silicon nitride ceramic.

In the comparative example, components electrically connected to the circuit patterns 6C, namely, the power semiconductor elements 8, the gate Al wire 9, the main Al wires 10, the anode Cu electrode 11, the cathode Cu electrode 12, and the control Cu electrode 13 are each connected to the circuit patterns 6C made of copper or copper alloy. In other words, as the electrical connection to the circuit patterns 6C, only the connection to copper or copper alloy is used. For example, the wires made of aluminum or aluminum alloy are bonded to the circuit patterns 6C made of copper or copper alloy by the ultrasonic bonding. In other words, the wires are connected in the manner that the different kinds of materials are bonded, namely, Al/Cu bonding. An oxide film is easily formed at the bonding interface, which may cause insufficient electrical bonding reliability.

In contrast, in this preferred embodiment (FIGS. 1 and 2), the circuit patterns 6A are made of aluminum or aluminum alloy, and also the pad plates 1C are made of copper or copper alloy. Thus, the bonding to the circuit patterns 6A made of aluminum or aluminum alloy or the bonding to the pad plates 1C made of copper or copper alloy can be selected as the electrical connection to the circuit patterns 6A. Consequently, a means of bonding with higher reliability can be selected according to the kinds of components electrically connected to the circuit board. This can increase the electrical bonding reliability. As a result, the durability of the power module 91 improves. In other words, the power module 91 can be used for a long period of time.

As described above, the bonding to aluminum or aluminum alloy or the bonding to copper or copper alloy can be selected, which is important especially in the direct bonding and advantageous for the ultrasonic bonding, for example.

The anode Cu electrode 11, the cathode Cu electrode 12, and the control Cu electrode 13 are directly bonded to the pad plates 1C made of copper or copper alloy. The electrodes are connected in such a manner that the same kinds of materials are bonded, whereby the electrical bonding reliability can be increased.

The gate Al wire 9 and the main Al wires 10 made of aluminum or aluminum alloy are directly bonded to the circuit patterns 6A made of aluminum or aluminum alloy. Thus, the wires can be connected in the manner that the same kinds of materials are bonded. This can increase the electrical bonding reliability. Moreover, using aluminum or aluminum alloy can reduce the cost of materials lower than the case of using expensive materials such as gold.

The bonding material 7 for bonding the power semiconductor elements 8 to the pad plates 1C contains silver. This can increase thermal conductivity, whereby the heat can be more efficiently removed from the power semiconductor elements 8. Therefore, the durability of the power module 91 against the heat cycle can be increased more.

Furthermore, the bonding material 7 containing silver is applied to the pad plates 1C made of copper or copper alloy, which can facilitate the bonding. In addition, it is difficult to perform the bonding by directly applying the bonding material 7 that contains silver to the circuit patterns 6A made of aluminum or aluminum alloy, and it still remains difficult even if a nickel plating is applied to the circuit patterns 6A.

The aluminum nitride ceramic having high thermal conductivity is used as the material for the insulating plate 5A, whereby heat dissipation efficiency can be increased. Therefore, the heat dissipation system, for example, the metal base plate 2 or an external radiator (not shown) provided in the power module 91 can be reduced in size.

### Second Preferred Embodiment

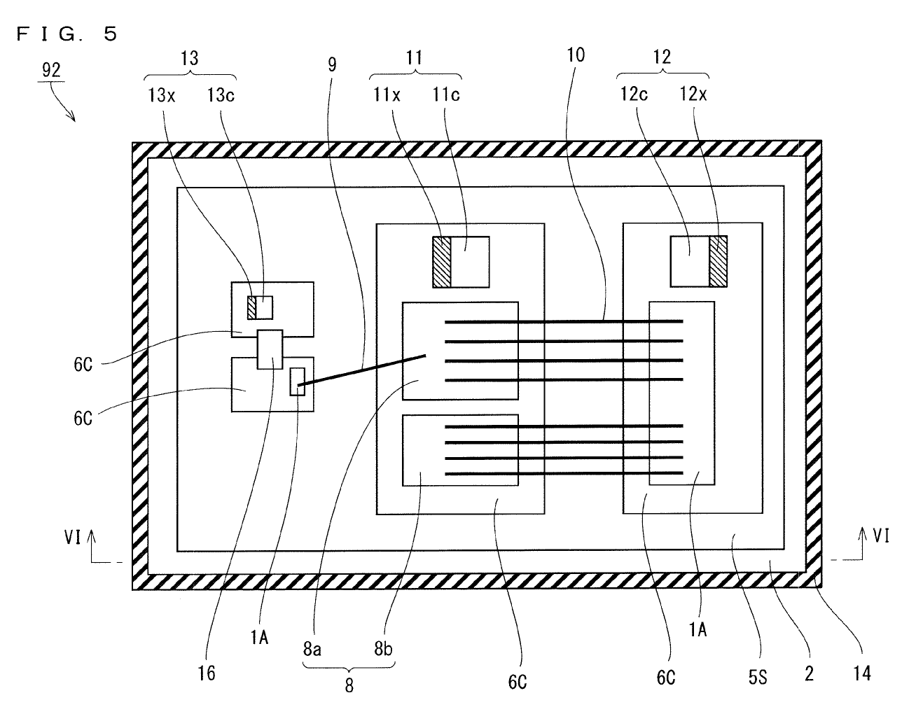

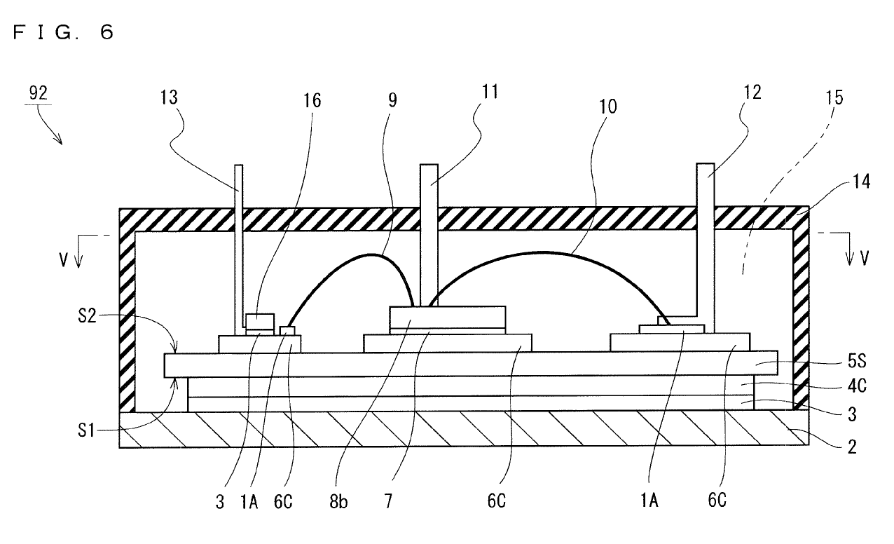

With reference to FIGS. 5 and 6, a power module 92 (power semiconductor device) of this preferred embodiment includes the circuit board and the power semiconductor elements 8 mounted on the circuit board. The circuit board includes the insulating plate 5S, the bonding pattern 4C, the circuit patterns 6C, and pad plates 1A.

The insulating plate 5S is made of silicon nitride ceramic. The insulating plate 5S has the lower surface S1 (first surface) and the upper surface S2 (second surface opposite to first surface).

The bonding pattern 4C is bonded to the lower surface S1 of the insulating plate 5S. The bonding pattern 4C is made of copper or copper alloy. The circuit patterns 6C are bonded to the upper surface S2 of the insulating plate 5S. The circuit patterns 6C are made of copper or copper alloy. The bonding pattern 4C and the circuit patterns 6C can be bonded to the insulating plate 5S by a direct bonded copper (DBC) or the AMB.

The pad plates 1A are bonded to the circuit patterns 6C. This bonding can be performed by the solid phase diffusion bonding in which the circuit patterns 6C and the pad plates 1A are pressurized in high temperature in a vacuum. The pad plates 1A only partially cover the circuit patterns 6C. The pad plates 1A are made of aluminum or aluminum alloy.

The power module 92 includes electrodes that are directly bonded to the circuit patterns 6C and made of any of copper and copper alloy. The electrodes are preferably bonded to the circuit patterns 6C by the ultrasonic bonding. Specifically, the power module 92 includes the anode Cu electrode 11, the cathode Cu electrode 12, and the control Cu electrode 13. These electrodes, namely, the external electrodes extend from the inside of the case 14 to the outside.

The power module 92 includes the gate Al wire 9 and the main Al wires 10 which are made of aluminum and aluminum alloy. The gate Al wire 9 and the main Al wires 10 are each bonded to the power semiconductor element 8 at one end. Furthermore, the gate Al wire 9 and the main Al wires 10 are each directly bonded to the pad plate 1A at the other end, and they are preferably bonded by the solid phase diffusion bonding, for example, the ultrasonic bonding.

The configuration except the one above is almost the same as the configuration of the first preferred embodiment as described above, so that the same or corresponding components have the same reference numerals and the descriptions will not be repeated.

In this preferred embodiment, the circuit patterns 6C are made of copper or copper alloy, and also the pad plates 1A are made of aluminum or aluminum alloy. Thus, the bonding to the circuit patterns 6C made of copper or copper alloy or the bonding to the pad plates 1A made of aluminum or aluminum alloy can be selected as the electrical connection to the circuit patterns 6C. Consequently, similarly to the first preferred embodiment, a means of bonding with higher reliability can be selected according to the kinds of components electrically connected to the circuit board. This can increase the electrical bonding reliability. As a result, the durability of the power module 92 improves. In other words, the power module 92 can be used for a long period of time.

As described above, the bonding to the aluminum or the aluminum alloy or the bonding to the copper or the copper alloy can be selected, which is important especially in the direct bonding and advantageous for the ultrasonic bonding, for example.

The wires made of aluminum or aluminum alloy are directly bonded to the pad plates 1A made of aluminum or aluminum alloy. Thus, the wires can be connected in the manner that the same kinds of materials are bonded. This can increase the electrical bonding reliability. In this preferred embodiment, the pad plate 1A is used for the bonding of the gate Al wire 9, but pad plates are not necessarily required to be applied to all wires. For example, while the main Al wires 10 serving as paths for a main current of the power module 92 are provided with the pad plate 1A, the gate Al wire 9 serving as a path for control signals may not be provided with the pad plate 1A.

The insulating plate 5S is made of silicon nitride ceramic, so that necessary mechanical strength can be obtained with its smaller thickness. Therefore, the power module 92 can be reduced in size.

In each of the preferred embodiments, a semiconductor material for the power semiconductor elements 8 may use, for example, Si or a wide band gap semiconductor such as SiC or GaN. The wide band gap semiconductor is suitable for use under high temperature. To make use of its advantage, it is particularly important to secure the electrical bonding reliability of the power semiconductor elements 8 as described above.

In addition, according to the present invention, the above preferred embodiments can be arbitrarily combined, or each preferred embodiment can be appropriately varied or omitted within the scope of the invention.

While the invention has been shown and described in detail, the foregoing description is in all aspects illustrative and not restrictive. It is therefore understood that numerous modifications and variations can be devised without departing from the scope of the invention.

What is claimed is:

1. A power semiconductor device, comprising:
a power semiconductor element; and
a circuit board having said power semiconductor element mounted thereon,
wherein said circuit board includes:
an insulating plate that is made of aluminum nitride ceramic and has a first surface and a second surface opposite to said first surface;
a bonding pattern that is bonded to said first surface of said insulating plate and made of any of aluminum and aluminum alloy;
a circuit pattern that is bonded to said second surface of said insulating plate and made of any of aluminum and aluminum alloy; and
a pad plate that is bonded to said circuit pattern, only partially covers said circuit pattern, and is made of any of copper and copper alloy.

2. The power semiconductor device according to claim 1, further comprising an electrode that is directly bonded to said pad plate and made of any of copper and copper alloy.

3. The power semiconductor device according to claim 1, wherein said power semiconductor element is bonded to said pad plate with a bonding material containing silver.

4. The power semiconductor device according to claim 1, further comprising a wire that is directly bonded to said circuit pattern and made of any of aluminum and aluminum alloy.

5. A power semiconductor device, comprising:
a power semiconductor element; and
a circuit board having said power semiconductor element mounted thereon,
wherein said circuit board includes:
an insulating plate that is made of silicon nitride ceramic and has a first surface and a second surface opposite to said first surface;
a bonding pattern that is bonded to said first surface of said insulating plate and made of any of copper and copper alloy;
a circuit pattern that is bonded to said second surface of said insulating plate and made of any of copper and copper alloy; and
a pad plate that is bonded to said circuit pattern, only partially covers said circuit pattern, and is made of any of aluminum and aluminum alloy.

6. The power semiconductor device according to claim 5, further comprising a wire that is directly bonded to said pad plate and made of any of aluminum and aluminum alloy.
